(19) United States
(12) Patent Application Publication
(10) Pub. No.: US 2010/0224958 A1
(43) Pub. Date: Sep. 9, 2010

(54) RF-IC PACKAGING METHOD AND CIRCUITS OBTAINED THEREBY

(75) Inventor: Lukas Frederik Tiemeijer, Eindhoven (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/739,380

(22) PCT Filed: Oct. 23, 2008
(86) PCT No.: PCT/IB08/54374

§ 371 Date: Apr. 22, 2010

(30) Foreign Application Priority Data
Oct. 30, 2007 (EP) 07119575.4

(51) Int. Cl. H01L 23/64; H01L 21/02; H01L 23/66

(52) U.S. Cl. 257/531; 438/381; 257/E23.01; 257/E21.022

(57) ABSTRACT

Typically, chips nowadays comprise a number of circuits as well as a number of inductors, often RF-inductors. These IC inductors are essential to realize the voltage controlled oscillators needed in the many fully integrated transceiver chips, serving a multitude of wireless communication protocols, that are provided to the market today. The present invention relates to an RF-IC packaging method, which virtually eliminates the long-range electromagnetic crosstalk between inductors and transmission lines of different parts of the circuitry.

### FIELD OF THE INVENTION

The present invention relates to an RF-IC packaging method, which virtually eliminates the long-range electromagnetic crosstalk between inductors and transmission lines of different parts of the circuitry.

### BACKGROUND OF THE INVENTION

Typically, chips, or integrated circuits (IC), nowadays comprise a number of IP-blocks (or building blocks) as well as a number of inductors, often RF-inductors. These IC inductors are essential to realize the voltage controlled oscillators needed in the many fully integrated transceiver chips, serving a multitude of wireless communication protocols, which are provided to the market today. A required inductance value is typically a few nH, and should preferably be adjustable to the application, whereas the quality factor should preferably be as high as possible. Preferably, an additional benefit could be a low net magnetic field, resulting in a lower magnetic coupling to other inductors (FIG. 1) or interconnect lines, which has been the aim of the special inductor layouts disclosed in WO1998005048 A1, WO2004012213 A1, WO2005096328 A1, and WO2006105184 A1.

WO98/05048 A1 relates to a planar magnetic field inductor/transformer and method that has a plurality of at least three planar loops/spiral conductor coils which are arranged one after another in a simple/compound loop fashion. The loops carry a current produced by a signal source, and the plurality of planar adjacent loops/spiral conductor coils are arranged to maximize cancellation of a moment of the plurality of loops/spiral conductor coils over a predetermined range.

WO2004/012213 Al discloses a planar inductance, in particular for monolithic HF oscillators, with planar spiral windings, wherein each winding is in the form of an “eight” (“8”) with three cross-conductors carrying current in the same direction and running between two loops.

WO2005/096328 A1 discloses a method and system for reducing mutual EM coupling between VCO resonators and for implementing the same on a single semiconductor chip. The inductors may be “8”-shaped, four-leaf clover-shaped, single-turn, multi-turn, rotated relative to one another, and/or vertically offset relative to one another.

WO2006/105184 A1 discloses a method and apparatus for use in an integrated circuit or printed circuit board for reducing or minimizing interference. An inductance is formed using two or more inductors coupled together and configured such that current flows through the inductors in different directions, thus at least partially canceling magnetic fields.

When designing a circuit, the configuration of the inductors, as well as the relative positions of portions of the circuit, can be tweaked to provide optimal interference or noise control.

As indicated above, RF-IC's comprising amongst others inductors are known.

The following documents relate to a single inductor and optimization thereof within one circuitry.

US2005/190035 discloses an on-chip inductor device for Integrated Circuits utilizing coils on a plurality of metal layers of the IC, with electrical connectors between the coils and a magnetic core for the inductor of stacked via's running between the coils. Films of magnetic material may be formed at the ends of the inductor to provide a closed magnetic circuit for the inductor. A high Q factor inductor of small (e.g., transistor) size is thus obtained.

WO2005/091499 relates to various spiral inductors projected on top of each other, formed on top of a dielectric material. Capacitor electrodes each occupying an area of 20-60% of the outer circumferential region of the relevant pattern are formed at the central parts of the first and second spiral inductors. A third dielectric substrate having a first ground layer formed thereon is laid on the upper surface of the first dielectric substrate. A second ground layer is laid on the lower surface of the second dielectric substrate.

EP0780853 relates to an inductor structure with improved Q compatible with typical integrated circuit fabrication includes a spiral inductor with a conductive plane between the resistive substrate of the integrated circuit and the spiral inductor which reduces the power loss of the inductor. A pattern of segments may be formed in the conductive material to prevent Eddy currents from flowing through the conductive plane and reducing the inductance of the spiral inductor. Optimizing the pattern in which the segmented conductive plane is formed can enhance the Q of the inductor. The segmented conductive plane may be fabricated out of metal, polysilicon or a heavily-doped region of the substrate.

US2003127686 relates to integrated circuits having symmetric inducting devices with a ground shield. In one embodiment, a symmetric inducting device for an integrated circuit comprises a substrate, a main metal layer and a shield. The substrate has a working surface. The main metal layer has at least one pair of current path regions. Each of the current path region pairs is formed in generally a regular polygonal shape that is generally symmetric about a plane of symmetry that is perpendicular to the working surface of the substrate. The shield is patterned into segments that are generally symmetric about the plane of symmetry. Medial portions of at least some segments of the shield are formed generally perpendicular to the plane of symmetry as the medial portions cross the plane of symmetry.

On the contrary, the present invention relates to an RF-IC packaging method, which virtually eliminates the long-range electromagnetic crosstalk between inductors and transmission lines of different parts of the circuitry.

It is believed that typically the magnetic coupling factor c between two planar inductors at a distance d much larger than their individual diameters can be expressed as;

$$c = \frac{K}{{d}^{3}}$$

where K is a constant of proportionality. For an “8” shaped inductor according to WO2004/012213 A1 with two identical eyes at distances

d₁=d+Δ cos α, d₂=d−Δ cos α,

where 2Δ denotes the distance between the eyes, and a accounts for their angular orientation, generating identical but opposite magnetic fields, the resulting coupling factor can be calculated as:

$$c = \frac{K}{{d}_{2}^{3}} - \frac{K}{{d}_{1}^{3}} = K \frac{6 Δ {d}^{2} cos α - {Δ}^{3} {cos}^{3} α}{{( {d}^{2} - {Δ}^{2} {cos}^{2} α )}^{3}} = K \frac{ 6 Δ cos α}{{d}^{4}}$$

The magnetic coupling factor now drops with the fourth power of the distance instead of with the third power of the distance. Moreover when a victim inductor is aligned at an angle α of 90 degrees, with the axis through the inductor eyes, the cancellation will be complete and the magnetic coupling factor will become zero. When two 8 shaped inductors according to WO2004/012213 A1 are combined into a clover shaped inductor as disclosed in WO2005/096328 A1, again their residual fields can be made to approximately cancel each other, and, as a result, at large distance the magnetic coupling factor is expected to drop with the fifth power of the distance.

Unfortunately, for the same area and track density, compared to a standard O-shaped inductor, EM simulations show that the “8” shaped inductor has a 25% lower Q-factor, whereas the clover shaped inductor has a 50% lower Q-factor. Thus, a problem associated with these specially shaped inductors is their lower Q-factor.

Problems and disadvantages of the low magnetic field inductors proposed to date to minimize undesired magnetic coupling between the different inductors of a circuit is their increased complexity, their reduced Q-factor and the fact that inductors need to be positioned at mutual sweet-spots for the best reduction of the inductive coupling. In a circuit with many different inductors this will be a difficult task, requiring a complicated and thus problematic design process, where many compromises have to be made, and in general EM simulations show that the overall reduction in inductive coupling might be limited to about 20 dB.

It is the aim of the RF-IC packaging method and circuits obtained thereby, disclosed in the present invention, to provide an alternative method and circuits to solve one or more of the above mentioned problems. The present method and circuits reduce magnetic coupling between the IC inductors, without needing to resort to special layouts and special configurations, which generally have a lower Q-factor per area efficiency, require dedicated inductors and inductor models, plus dedicated tools to determine their optimum relative alignment.

### SUMMARY OF THE INVENTION

The present invention provides a semiconductor device for eliminating long range electromagnetic crosstalk comprising an integrated circuit with more than one inductor, further comprising a first layer on a first side of the semiconductor device capable of generating Eddy-currents, and a second layer on a second side of the semiconductor device capable of generating Eddy-currents, which first and second layer are located on either side of the more than one inductor, an IC comprising said device, a use of said device, and a method of producing said device.

### DETAILED DESCRIPTION OF THE INVENTION

Thus, the present invention provides in a first aspect a semiconductor device for eliminating long range electromagnetic crosstalk comprising an integrated circuit with more than one inductor, wherein the more than one inductor are formed in the outer layers of the integrated circuit, and wherein the more than one inductor are substantially in the same horizontal plane of the device, further comprising a first layer on a first side of the semiconductor device capable of generating Eddy-currents, and a second layer on a second side of the semiconductor device capable of generating Eddy-currents, which first and second layer are located on either side of the more than one inductor.

The semiconductor device may be a complex chip, or integrated circuit, such as an WLAN receiver chip, comprising as many as ten inductors, or more, as well as a large number of IP-blocks, or building blocks (see e.g. FIG. 1). Typically, such a device is packaged in a conventional way, wherein the IC and inductors are connected to the outside world (see bonding in e.g. FIG. 1), and are further protected from environmental influences. As can be seen from the example in FIG. 1, typically the more than one inductor are substantially in the same horizontal plane of the device, e.g. the outer, typically back-end, layers from a semiconductor device. These outer layers may comprise dielectric layers, metal layers, and interconnects and/or via's, in as far as IC's are concerned, and may comprise dielectric layers and metal layers in as far as inductors are concerned. Nowadays, as is detailed below, inductors may also be formed of coils in various layers, projected on top of each other, implying the need of via's or similar structures, connecting coils of the inductor.

Typically an inductor occupies a relatively large portion of the device, as can e.g. be seen from FIG. 1. Inductors are typically used to generate RF or HF. Furthermore, it is noted that at present it is difficult or virtually impossible to integrate inductors into circuitry.

Therefore inductors are typically formed in the outer (metal) layers of a semiconductor device, such as a chip, and preferably the inductors are formed in areas of the chip were no other components, such as logic or memory, are present.

In an IC-package, such as disclosed in the present invention, two layers, or plates, capable of generating Eddy-currents, such as electrically conductive metal plates, are placed below and above the IC inductors, at a certain distance, which distance is amongst others determined by the thickness of a semiconductor device. Preferably the inductors present on a semiconductor device are all fully covered, i.e. covered by the first layer on the first side and by the second layer on the second side. The distance of a layer to the inductor may typically be from 20% to 100% of the outer diameter of the biggest inductor in the circuit, and thus are preferably from 10 to 200 μm, more preferably from 30 to 100 μm, such as at 50 μm.

However, despite being less preferable, the distance may vary from about 1 to about 500 μm, such as from 5 to 300 μm, preferably from 10 to 200 μm, more preferably from 30 to 100 μm, such as at 50 μm, depending on amongst others the process used, the specific materials used, etc. It is noted that for very small distances the quality factor of specific inductors is, as a consequence, sacrificed. Preferably both layers are located at approximately equal distance from the inductor. It is believed that the latter arrangement offers the bets results, in terms of eliminating the long-range electromagnetic crosstalk between inductors and transmission lines of different parts of the circuitry.

Preferably, the first layer is integrated into the integrated circuit, i.e. is formed in one of the outer layers of the IC.

Preferably the second layer is integrated into the integrated circuit, e.g. formed on the bottom side of the IC.

These configurations offer advantages, such as ease of processibility, as no extra masks or processing steps are needed.

The two layers, or plates, capable of generating Eddy-currents, preferably comprise a metal and/or other electrically conducting material. Suitable materials are for instance copper, aluminum, tungsten, silicon, or other metals applicable in a semiconductor process.

A further advantage of the present invention is that the first layer and/or second layer may be electrically grounded. Clearly grounding of said layers offers advantages, such as better shielding of electrical fields.

Another advantage of the present invention is that the first layer and/or second layer and integrated circuit may be electrically grounded to the same ground. Clearly grounding of said layers offers advantages, such as better shielding of electrical fields.

The above layers may be formed as a layer covering the whole area of the IC.

The layer may also cover a substantial part of the IC, such as 50%, or 75%, or 90% thereof.

The layer may also be limited in area, covering only the inductors. Here, the term “covering” refers to a projection of the layer onto the inductor, which projection is perpendicular to the one or more of the axis of the inductor, whereby the projection of the layer covers the inductor. It is noted that one layer is projected form the top side, and one layer is projected from the bottom side. The projection may cover an inductor largely, e.g. such as 90% or more of its area, though preferably it covers the inductor fully, more preferably its projection extends beyond the boundaries of the inductor, covering also an adjacent area, such as to an area which may be much larger than the area of the inductor, such as twice that area (see FIG. 6). Further more, combinations of the above may be made. For instance, two inductors may be covered by one mutual layer, as is indicated in FIG. 7.

The above layers may be continuous, or may be partly interrupted, e.g. by a dielectric, as long as Eddy currents may be generated. Each layer may be in one of the outer layers of the semiconductor device, or it may be split up into several of the outer layers.

Typically, various designs of the above layers may be envisaged, which design can be tailored to requirements of specific designs.

It is believed that these metal plates form a microwave waveguide where transverse electric (TE) waves are allowed to propagate, but where transverse magnetic waves (TM) are not allowed to propagate below a cut-off frequency given by:

$${f}_{c} = \frac{{ω}_{c}}{2 π} = \frac{c}{2 h \sqrt{μ ɛ}}$$

where h denotes the vertical height between the two metal plates. As can be seen, this cut-off frequency is the frequency where exactly half a wavelength fits between the two metal plates.

Microwave waveguide theory tells that the E and B fields of such an evanescent mode are exponentially attenuated with distance z as:

$$\begin{matrix}E ( z ) \\ B ( z )\end{matrix} \} = \{ \begin{matrix}{E}_{o} {e}^{- π \frac{z}{h} \sqrt{1 - \frac{{ω}^{2}}{{ω}_{c}^{2}}}} \\ {B}_{o} {e}^{- π \frac{z}{h} \sqrt{1 - \frac{{ω}^{2}}{{ω}_{c}^{2}}}}\end{matrix}$$

The exponential attenuation of the magnetic (B) field which can be achieved this way is much more effective than the enhanced power law roll-off with can be achieved with the known low magnetic field layouts.

The invention is further illustrated by the following figures, which are not intended to limit the scope of the present invention. It will be clear for the person skilled in the art that combinations of various embodiments are also envisaged and fall under the scope of the present invention.

In a further aspect the invention relates to an IC comprising a semiconductor device according to the invention. Examples of such IC's are wireless applications, such as GSM/mobile phones, wireless internet, walkie talkie, FM radio's, transmitting and receiving modules for GSM base stations.

In another aspect the invention relates to a use of a semiconductor device according to the invention, for eliminating long range electromagnetic crosstalk.

In yet a further aspect the invention relates to a method of producing a semiconductor device according to one of the preceding claims, comprising providing an integrated circuit, with more than one inductor, applying a first layer on a first side of the semiconductor device capable of generating Eddy-currents, and applying a second layer on a second side of the semiconductor device capable of generating Eddy-currents, which first and second layer are located on either side of the inductor.

Preferably one of the embodiments described above is provided by the above method.

Such a method comprises processing steps known per se to the person skilled in the art.

### BRIEF DESCRIPTION OF THE DRAWINGS

FIG. 1 is an example of an NXP WLAN transceiver chip containing 10 inductors.

FIG. 2 is an example of an RF-IC package according to the present invention.

FIG. 3 is an example of a Sonnet EM simulation set-up.

FIG. 4 shows the magnetic coupling c versus distance.

FIG. 5 shows a simulated inductance and quality factor of the 400 mm diameter octagonal inductor when sandwiched between two metal plates for different values of the cavity height h.

FIG. 6 shows two layers fully covering an inductor.

FIG. 7 shows two layers covering two inductors.

### DETAILED DESCRIPTION OF THE DRAWINGS

The figures are now explained in further detail.

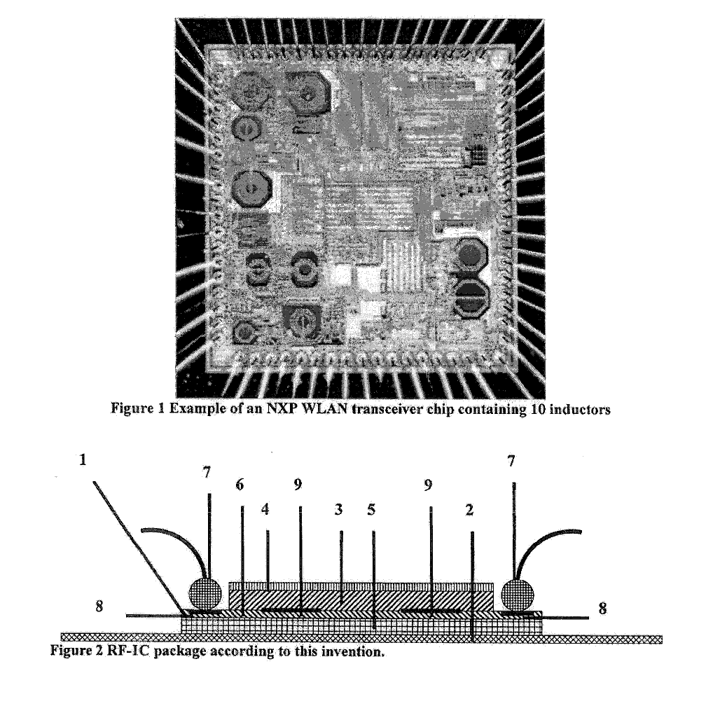

FIG. 1 shows an example according to the present invention, wherein the semiconductor device is a complex chip, such as a WLAN receiver chip, comprising as many as ten inductors, as well as a large number of IP-blocks.

FIG. 2 shows the RF package disclosed in this invention. The circuit die (1) is mounted on a metal carrier (2) and covered with a dielectric (3) and metal cover (4). Further, the silicon substrate (5), intermetal dielectric (6), wire bonding (7), and passivation (8) are shown. The inductors (9) are placed on top of the intermetal dielectric. The space between the metal carrier and metal cover is optimized to maximize the attenuation of TM modes without degrading inductor performance too much. To achieve an optimal suppression of TM modes the IC substrate will have to be thinned to about 100 μm. There are several methods available to apply the cover dielectric and cover metal, which can be selected for minimal additional costs and ease of post-processing. A method where first the entire wafer is covered with dielectric and metal, after which first the bond pad openings are made, followed by slicing and mounting of the individual dies, seems attractive for this.

FIG. 2 shows an example of an RF-IC package according to the present invention. The circuit die is mounted on a metal carrier and covered with a dielectric and metal cover. The space between the metal carrier and metal cover is optimized to maximize the attenuation of TM modes without degrading inductor performance too much.

Building the invention should be clear to those skilled in the art. Here guidelines will be given for selecting the proper spacing between the top and bottom metal layers, and the benefits of the invention will be further illustrated.

We start considering the case of an inductor in close vicinity of a metal ground plate. If the conductivity of the ground plate is sufficiently large, a mirror current is induced in this ground plate at an apparent depth equal to the height of the inductor above the ground plate. The inductor and its mirror image generate identical, but oppositely directed, magnetic fields, and as before the resulting coupling factor can be calculated as:

$$c = \frac{K}{{d}_{o}^{3}} - \frac{K}{{d}_{m }^{3}} = \frac{K}{{d}^{3}} - \frac{K}{{\sqrt{{d}^{2} + 4 {h}^{2}}}^{3 / 2}} \approx K \frac{6 {h}^{2}}{{d}^{5}}$$

It can be seen that adding a single metal plate creates a mirrored inductor, which enhances the roll-off from the third to the fifth power with distance. Adding a second cover metal plate not only creates a second mirror image, but also adds an infinite number of higher order reflections of the original inductor with alternating magnetic fields. The number of higher order reflections, contributing to the cancellation of the magnetic fields, increases with distance from the original inductor, and as a result an exponential decrease in net magnetic field strength is expected in line with the microwave waveguide theory given in a previous section.

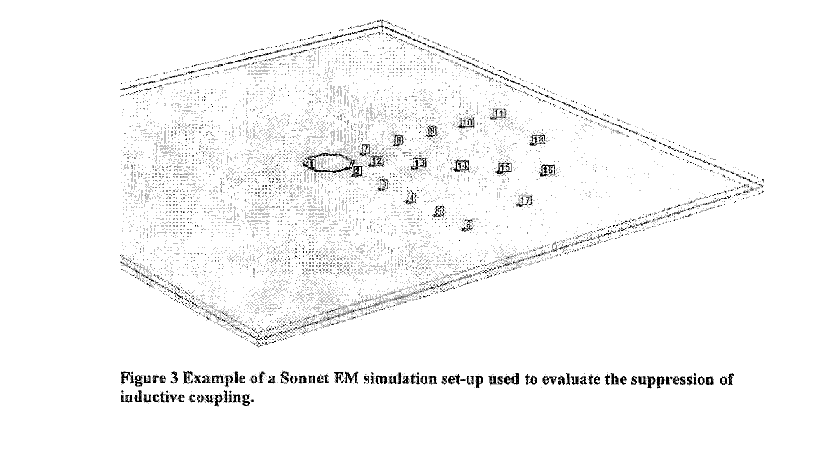

Sonnet EM simulation software has been used to quantify in more detail the reduction in coupling factor which can be achieved in different situations. FIG. 3 shows the Sonnet EM simulation set-up used to evaluate suppression of inductive coupling. This set-up contains 17 victim single loop circular inductors, placed at different distances up to 1.8 mm, and at 5 different angles from a central 400 μm diameter inductor under test. The (magnetic) coupling between the inductors is calculated using:

$${c}_{x} = \sqrt{\frac{{imag ( {Z}_{1 x} )}^{2}}{imag ( {Z}_{11} ) imag ( {Z}_{xx} )}}$$

where Z represents the Z parameter matrix simulated by the Sonnet EM model.

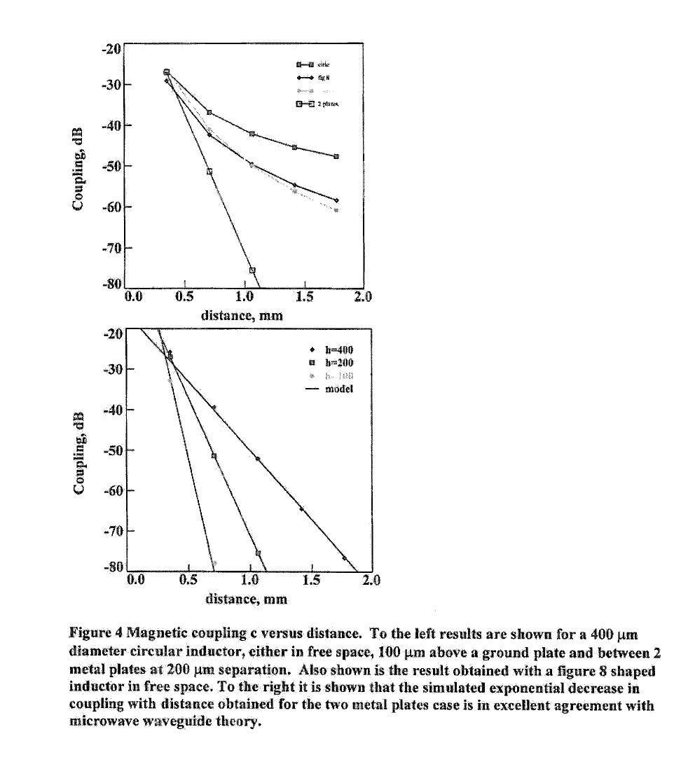

FIG. 4 shows the relation between magnetic coupling c versus distance. To the left results are shown for a 400 μm diameter circular inductor, either in free space, 100 μm above a ground plate, or between 2 metal plates at 200 μm separation. Also shown is the result obtained with a FIG. 8 shaped inductor in free space.

To the right it is shown that the simulated exponential decrease in coupling with distance obtained for the two metal plates case is in excellent agreement with microwave waveguide theory.

The magnetic coupling of the victim inductor with a conventional 400 μm octagonal inductor in free space is found to decrease with the third power of distance, whereas for a specific “8” shaped inductor, under a 45 degree angle, the coupling is found to decrease with the fourth power of distance. When the conventional octagonal inductor is placed 100 μm above a metal ground plate, the coupling is found to decrease with the fifth power of distance, and drops below that of the “8” shaped inductor beyond about 1.2 mm. Adding the top metal cover 100 μm above the inductor reduces the coupling drastically further, and causes a transition from a power law decay to an exponential decay. In fact the exponential decay found for the simulated coupling factors appears to be in excellent agreement with the characteristic decay length h/p, predicted by microwave waveguide theory for the TM evanescent wave, as represented by the solid lines labeled “model” in the right part of FIG. 4. As a consequence, to maximize the suppression of the TM waves one thus needs to minimize the cavity height h.

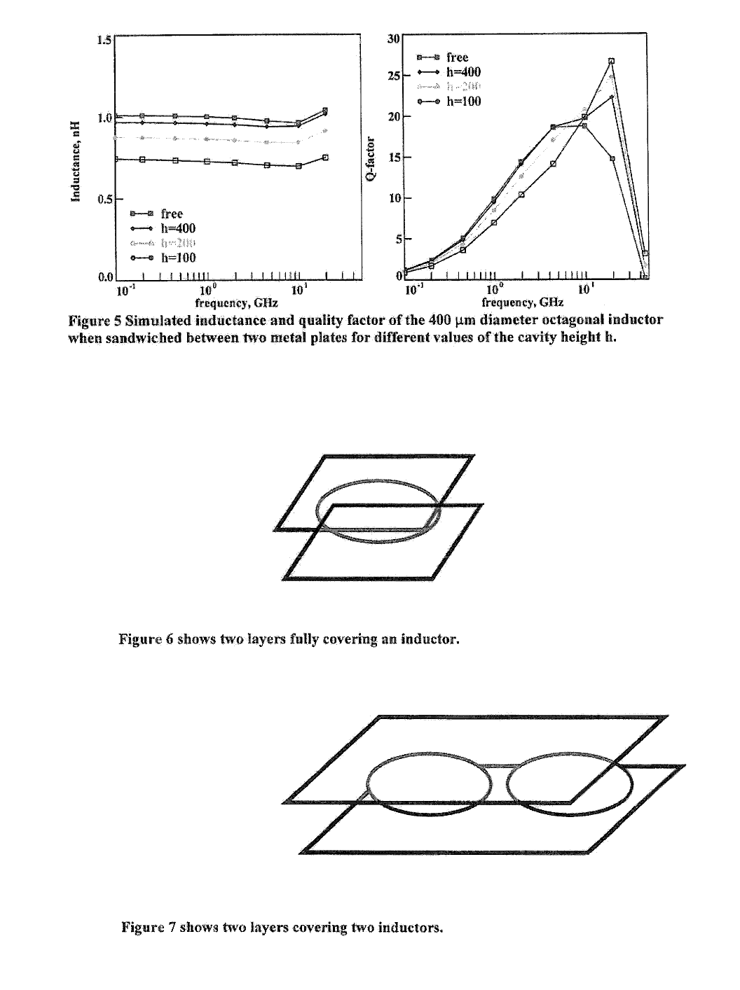

The impact of selecting a height h, which is considerably less than the inductor outer diameter on the inductor performance, as, is illustrated in FIG. 5.

FIG. 5 shows simulated inductance and quality factor of the 400 μm diameter octagonal inductor, when sandwiched between two metal plates in a semiconductor device for different values a cavity height h.

A cavity height equal to the inductor diameter causes a 4% reduction in inductance, whereas a cavity height equal to half the inductor diameter causes a 14% reduction in inductance, and a cavity height equal to a quarter of the inductor height causes a 27% reduction in inductance. The impact on inductor Q-factor is therefore small. When one compares this with an analysis of the performance of specific optimal “8” shaped and clover shaped inductors, one sees that a much more effective reduction in magnetic coupling at considerably less degradation of the Quality factor, compared to a circle, set at 100%, derived from the low-frequency L/R ratio is achieved. This is shown in the table below.

TABLE 1

| | | | | 8- | | |
|---|---|---|---|---|---|---|
| Layout | circle | h = d | h = d/2 | shaped | h = d/4 | clover |
| Rel Q | 100% | 96% | 86% | 78% | 73% | 58% |
| C@ | −48 dB | −76 dB | −124 dB | −58 dB | −213 dB | −62 dB |
| 1.8 mm | | | | | | |

Even more, for the inductors without patterned ground shield evaluated at present, the peak Q-factor increases when the cavity height is reduced, due to a lowering of the effective substrate resistance. When a patterned ground shield is used to prevent Q-factor degradation due to the substrate resistance, this beneficial effect will disappear. It should be noted that the Sonnet EM simulation software could not confirm extrapolated coupling factors below −90 dB. This is likely to be due to limitations of the software. Microwave waveguide theory predicts that any EM power coupled into the TE waveguide mode would experience much less attenuation, and could cause a lower limit in the crosstalk between components. These TE waveguide modes can be exited by vertical components of E-fields and/or currents. In a preferred embodiment according to the present invention it is therefore desirable that all interconnect and transmission lines, inductors, transformers and other passive structures are made as planar as possible, e.g. falling within a horizontal plane with thickness of less than 5 μm, preferably of less than 3 μm, more preferably of less than 1 μm, even more preferably of less than 0.5 μm, most preferably less than 0.25 μm, in order that the EM power coupled into the TE mode is minimized. Fortunately with the current planar IC technology where all RF currents flow in a few top-metal layers it is possible that this may be almost automatically achieved.

To check whether TE modes could cause relevant amounts of cross-talk, the cross-talk simulations were repeated for a similar 400 μm diameter two-turn inductor, where the second inductor turn was located 6 μm below the first inductor turn. Although this resulted in a relatively two times higher resistance and three times higher inductance, the vertical height of this structure was too small, to induce a noticeable deviation from the behavior shown in FIG. 4. In fact, for the h=200 μm case at about 1 mm distance, the inductive coupling of the single and two-turn versions were found to agree within 0.1 dB. It was further found that the suppression of the inductive coupling does not critically depend on the conductivity of the carrier and cover metals. In fact, the use of realistic 10 μm thick aluminum layers for the carrier and cover metals rather than perfect conductors was found to further reduce the inductive coupling by about 0.3 dB at about 1 mm distance. To achieve the package properties disclosed in this invention, it is not required that the carrier and cover metals are connected to the circuit ground. There could however be cases where additional measures to suppress the propagation of TE modes are desirable. These measures could consist of adding metal via's to connect the carrier and cover metals to the circuit to short circuit undesirable transverse electric fields. These via's could either be located near the bond-pads of the circuit, to prevent EM fields from the bond-wires from entering the circuit cavity, or between different parts of the circuit, to prevent further crosstalk. Selecting proper processing methods for the latter case should be clear for those skilled in the art.

The present invention has for instance the following applications and advantages. It minimizes inductive crosstalk, while maximizing the inductor Q-factor and minimizing the area needed for the inductors. This is important in many application fields of these devices, which range from low power fully integrated wireless transceiver chips, serving a multitude of communication protocols, to power amplifier modules, delivering hundreds of watts, but integrating only a few RF amplification stages. The invention discloses a packaging method, which practically eliminates, rather than reduces, the long range electromagnetic crosstalk. Compared to the known methods for suppressing inductive crosstalk this method is much more effective, since it does not require careful positioning in mutual sweet-spots and specialized inductor layouts.

FIG. 6 shows two layers fully covering an inductor, one layer being above the inductor, one layer being below the inductor. Other elements and layers are left out.

FIG. 7 shows two layers fully covering two inductors, one layer being above the inductors, one layer being below the inductors. Other elements and layers are left out.

1. Semiconductor device for eliminating long range electromagnetic crosstalk, comprising an integrated circuit with more than one inductor, wherein the more than one inductor are formed in the outer layers of the integrated circuit, and wherein the more than one inductor are substantially in the same horizontal plane of the device, further comprising a first layer on a first side of the semiconductor device capable of generating Eddy-currents, and a second layer on a second side of the semiconductor device capable of generating Eddy-currents, which first and second layer are located on either side of the more than one inductor.

2. Semiconductor device according to claim 1, wherein the first layer is integrated into the integrated circuit.

3. Semiconductor device according to claim 1, wherein the second layer is integrated into the integrated circuit.

4. Semiconductor device according to claim 1, wherein the first layer and second layer comprise an electrically conducting material.

5. A semiconductor device according to claim 1, wherein the first layer, second layer, or combination thereof, is electrically grounded.

6. Semiconductor device according to claim 1, wherein the first layer, second layer, integrated circuit, or combination thereof, is electrically grounded to the same ground.

7. IC comprising a semiconductor device according to claim 1.

8. A semiconductor device according to claim 1 functioning to eliminate long-range electromagnetic crosstalk.

9. Method of producing a semiconductor device for eliminating long range electromagnetic crosstalk, the method comprising:
providing an integrated circuit, with more than one inductor,
applying a first layer on a first side of the semiconductor device capable of generating Eddy-currents, and
applying a second layer on a second side of the semiconductor device capable of generating Eddy-currents, which first and second layer are located on either side of the inductor.

10. The semiconductor device according to claim 4, wherein the electrically conducting materials includes a metal, polysilicon, or heavily-doped silicon, or combinations thereof.
